(19) United States
(12) Patent Application Publication
(10) Pub. No.: US 2018/0286991 A1
(43) Pub. Date: Oct. 4, 2018

(54) COATED FOIL-BASED METALLIZATION OF SOLAR CELLS

(71) Applicant: SUNPOWER CORPORATION, San Jose, CA (US)

(72) Inventors: Paul Loscutoff, Castro Valley, CA (US); Richard Hamilton Sewell, Los Altos, CA (US)

(21) Appl. No.: 15/476,814

(22) Filed: Mar. 31, 2017

(51) Int. Cl. H01L 31/02; H01L 31/0216; H01L 31/0224; H01L 31/0465; H01L 31/05; H02S 40/36; H02S 40/30; H02S 30/00

(52) U.S. Cl. CPC H01L 31/02008; H01L 31/02167; H01L 31/022425; H02S 30/00; H01L 31/0512; H02S 40/36; H02S 40/30; H01L 31/0465

(57) ABSTRACT

Coated foil-based approaches for metallization of solar cells, and the resulting solar cells, are described. For example, a solar cell includes a substrate. A semiconductor region is disposed in or above the substrate. A conductive contact structure is disposed on and is in electrical contact with the semiconductor region. The conductive contact structure includes a metal foil portion having a first side facing the semiconductor region, and a second side opposite the first side. The second side of the metal foil portion is at least partially coated with an etch-resistant insulating film.

### TECHNICAL FIELD

Embodiments of the present disclosure are in the field of renewable energy and, in particular, include coated foil-based approaches for metallization of solar cells, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures.

### BRIEF DESCRIPTION OF THE DRAWINGS

FIG. 1 illustrates a cross-sectional view of a solar cell, in accordance with an embodiment of the present disclosure.

FIG. 2 illustrates a cross-sectional view of another solar cell, in accordance with another embodiment of the present disclosure.

FIGS. 3A-3D illustrate cross-sectional views of various stages in the fabrication of a solar cell using foil-based metallization, in accordance with an embodiment of the present disclosure.

FIGS. 4A-4D illustrate cross-sectional views of various stages in the fabrication of another solar cell using foil-based metallization, in accordance with another embodiment of the present disclosure.

FIG. 5 is a flowchart listing operations in a method of fabricating a solar cell, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

Coated foil-based approaches for metallization of solar cells, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as emitter region fabrication techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are solar cells. In one embodiment, a solar cell includes a substrate. A semiconductor region is disposed in or above the substrate. A conductive contact structure is disposed on and is in electrical contact with the semiconductor region. The conductive contact structure includes a metal foil portion having a first side facing the semiconductor region, and a second side opposite the first side. The second side of the metal foil portion is at least partially coated with an etch-resistant insulating film.

In another embodiment, a solar cell includes a substrate. A semiconductor region is disposed in or above the substrate. A conductive contact structure is disposed on and is in electrical contact with the semiconductor region. The conductive contact structure includes a metal foil portion having a first side facing the semiconductor region, and a second side opposite the first side. The second side of the metal foil portion is at least partially coated with an etch-resistant insulating film. A welding joint is joining the metal foil portion to the semiconductor region. The first side of the metal foil portion is at least partially coated with an etch-resistant insulating film, the etch-resistant insulating film surrounding the welding joint.

In another embodiment, a solar cell includes a substrate. A semiconductor region is disposed in or above the substrate. A conductive contact structure is disposed on and is in electrical contact with the semiconductor region. The conductive contact structure includes an aluminum foil portion having a first side facing the semiconductor region, and a second side opposite the first side. Both the first side and the second side of the aluminum foil portion have a coating thereon, the coating selected from the group consisting of a poly(p-xylylene) polymer film and a fluorocarbon film.

Also disclosed herein are method of fabricating solar cells. In one embodiment, a method of fabricating a solar cell includes forming a plurality of alternating N-type and P-type semiconductor regions in or above a substrate. The method also includes adhering a metal foil to the alternating N-type and P-type semiconductor regions, the metal foil having a first side facing the semiconductor region, and a second side opposite the first side, wherein the second side of the metal foil is coated with an etch-resistant insulating film. The method also includes patterning the etch-resistant insulating film coated on the second side of the metal foil to expose regions of the second side of the metal foil corresponding to locations between the alternating N-type and P-type semiconductor regions. The method also includes, subsequent to patterning the etch-resistant insulating film, etching the metal foil to isolate portions of the metal foil, the portions of the metal foil corresponding to the alternating N-type and P-type semiconductor regions.

One or more embodiments described herein provides a technique for patterning a metal foil (such as an aluminum foil) bonded to a solar cell. In an embodiment, a metallization structure for interdigitated back-contact (IBC) solar cell is described. The metallization structure is foil-based and may require structuring or patterning into parts that are electrically separated from one another, and which can be accomplished without numerous processing operations. Some embodiments described below provide a method for imparting etch resistance and electrical isolation to aluminum foils. For example, a thin, conformal dielectric film with chemical resistance may be coated on one or both sides of a piece of aluminum foil, which is then attached to a solar cell through a method such as laser welding or thermo-compression bonding. The foil can then have a pattern grooved therein to create area specific imperfections or selective removal of the coating. These areas may be more susceptible to chemical etching than the non-grooved regions of the cell. Additionally, if the bonded side of the foil is coated, and the film is chosen appropriately, the bonding process can break the coating such that forming a bond to the solar cell is still possible, but the underside of the foil is coated with chemical resistant film. Upon etching through the grooved lines in the film, the coating on the underside can prevent undercut from the etchant, and maintain the full metal foil thickness. In a specific embodiment, the coating is one from the family of parylene coatings, also referred to as a poly(p-xylylene) polymer film, are used to provide an etch-resistant coating on a metal foil for solar cell metallization.

To provide context, a potential issue facing foil metallization for solar cell fabrication is partial foil removal after bonding, which may be needed in order to isolate opposite polarity metal fingers. A wet approach for the partial foil removal typically includes a chemical etch, where selectivity between the bulk metal fingers and the areas targeted for removal can be achieved by either a chemically resistant etch mask on the fingers or a partial removal of the metal in the targeted removal regions by laser grooving prior to etching the sample. In either of these process flows, there may be an issue with the chemical etch process tolerance, where the metal needs to be cleared completely to isolate the fingers, but over-etching can possibly thin the foil from the top side, undercut an underlying metal seed layer, and/or thin the foil by etching from the backside. Such treatments may even compromise the bonding points of a metal foil to a metal seed layer and/or to an underlying semiconductor region. To date, this has been managed by timing the wet etch in order to create isolation with minimal over-etching. However, the resulting small process window may raise issues at high volume manufacturing (HVM).

To provide further context, metallization of solar cells can invoke a large cost factor in the fabrication of solar cells, either driven by material costs (such as current mainstream silver metal paste printing) or by a large number of processing operations and the associated capital expense. Aluminum lends itself to low material costs, but the structuring techniques may be difficult or cumbersome when depositing full-area Al films such as through physical vapor deposition (PVD; e.g., evaporation, sputtering) films, or/and when using Al foils. Aluminum paste printing and the inherent structuring of the printing is possible in principal, but in practice Al paste printing is not well-suited for contacting n-type material, and the firing process of the Al paste may destroy the n-type and p-type surface doping structures that are implemented in silicon wafers typically by thermal diffusion of dopants.

Other approaches are therefore being investigated, such as the use of Al foils. An Al foil may provide a readily available sheet of metal of relatively high conductivity which may be directly attached to the solar cell. Laser-welding has been investigated for attaching the Al foil to the solar cell, which may feature a first, thin (thus cost-effective) PVD-deposited metallization layer. While challenges still exist for such an approach, a particular challenge is to apply such a technique in a cost effective manner to interdigitated back contact (IBC) solar cells. These solar cells have both types of contacts at the rear of the solar cell, and therefore the metallization layer (the foil) has to be separated (structured) into two parts without electrical connection.

To provide even further context, a pure “mask and etch” approach should etch all the way through Al foils that are often thick, e.g., greater than 20 microns. This can be expensive and difficult from a manufacturing point of view. It is to be appreciated that the amount of etching may be reduced by making use of the fact that laser ablation can create a groove in the Al foil prior to etching. However, the laser groove must not penetrate too deep in order to avoid laser damage to the solar cell. Consequently, the laser grooving does only moderately facilitate the separation of the Al foil pieces by etching, yet it requires the use of an additional expensive equipment (i.e., the laser system).

Addressing one or more of the above issues, in accordance with an embodiment of the present disclosure, a chemical resistant film is deposited on an aluminum foil prior to bonding. The chemical resistant film can play the role of a mask that is patterned at the same time the foil is grooved. In an exemplary embodiment, poly(p-xylylene) polymer films have excellent etch resistance and can be deposited conformally as a thin film. Since poly(p-xylylene) polymer films are high molecular weight polymers, they typically have high melting points, e.g., ranging from 290-420 degrees Celsius, depending on the specific poly(p-xylylene) polymer film. In a specific embodiment, such as a poly(p-xylylene) polymer film, is deposited on a metal foil prior to bonding to a solar cell. For bonding, laser welding or thermo-compression bonding, or the like, may be used. In one embodiment, the coating is very thin from an optical perspective and, as such, there is minimal absorption of a laser that is used for welding or grooving the foil. After bonding, a laser groove or other indentation formed creates a discontinuity in the poly(p-xylylene) polymer film, providing regions that are susceptible to chemical etching. In one particular embodiment, the melting point of the poly(p-xylylene) polymer film is such that another layer of laser weld, e.g., from a cell metal foil to a cell interconnect, melts the poly(p-xylylene) polymer film upon the laser upon laser exposure so as to not hinder bond formation.

In an embodiment, an extension of a single-side coating process involves coating both sides of the metal foil. Similar to the case described above for the foil to interconnect weld, a coating such as a poly(p-xylylene) polymer film does not inhibit formation of a laser weld between a metal seed layer on the solar cell and a metal foil layer. The additional coating on the back side of the foil can be included to add a layer of etch protection to the metal foil, since upon first punch-through of the chemistry in the groove the etchants have access to the back side of the foil for otherwise undesired etching. Since a substantial over-etch may be required to create a robust process for metal finger electrical isolation, any over-etch time otherwise results in thinning of a standard foil from both sides. However, with both sides coated, foil etching is mitigated or altogether eliminated in all non-grooved or indented regions, both on the top side and back side of the metal foil. In either a single-side coated process flow or a dual-side coated process flow, in an embodiment, such coatings are left in place for a module build, and add to the overall chemical resistance of the metal foil.

More specifically, one embodiment involves first application of a metal layer, e.g., 100 nanometer thick aluminum (Al), onto a silicon wafer that has undergone a device fabrication portion of a solar cell process. In an embodiment, the aluminum foil first receives a protective coating on the surface that is either already patterned or is ultimately patterned or structured by grooves or indentations. The protective coating can be implemented to protect or sufficiently slow down the etching of the aluminum when brought in contact with an etchant that is used to clear out the aluminum in the grooves or indentations. The protective coating can become disrupted or perforated in the regions of the grooves that are formed by indentation. If such disruption of a protective coating is accomplished, the etch selectivity between those regions to be etched (grooves or indentations) and the remaining aluminum foil area can be greatly enhanced.

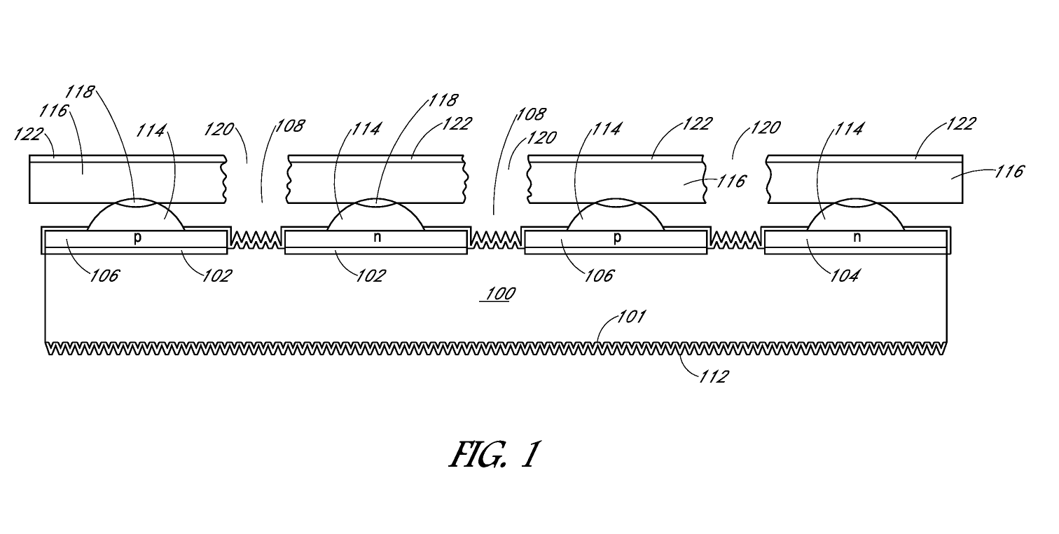

As an exemplary solar cell structure having a metal foil with a coated surface, FIG. 1 illustrates a cross-sectional view of a solar cell, in accordance with an embodiment of the present disclosure.

Referring to FIG. 1, a solar cell includes a substrate 100. A semiconductor region 104 or 106 is disposed in or above the substrate 100. A conductive contact structure 114/116 is disposed on and is in electrical contact with the semiconductor region 104 or 106. The conductive contact structure 114/116 includes a metal foil portion 116 having a first side facing the semiconductor region 104 or 106, and a second side opposite the first side. The second side of the metal foil portion is at least partially coated with an etch-resistant insulating film 122.

In an embodiment, as used herein, the etch-resistant insulating film 122 is a film that is coated on the metal foil and not formed from anodizing a surface of the metal foil, e.g., the etch-resistant insulating film 122 is not an anodized surface of aluminum foil. In an embodiment, the etch-resistant insulating film 122 is a dielectric film. In an embodiment, the etch-resistant insulating film 122 is not considered a conductive or metallic film.

In an embodiment, the etch-resistant insulating film 122 has a thickness suitable to avoid the presence of pin-holes in the film. In one such embodiment, the etch-resistant insulating film 122 has a thickness of at least 0.1 micron.

In an embodiment, the etch-resistant insulating film 122 is a poly(p-xylylene) polymer film. In one such embodiment, the poly(p-xylylene) polymer film has a thickness in the range of 0.1-5 microns. In another embodiment, the etch-resistant insulating film 122 is a fluorocarbon film. In one such embodiment, fluorocarbon film has a thickness in the range of 1-25 micron. In an embodiment, the etch-resistant insulating film 122 is base-resistant. In another embodiment, the etch-resistant insulating film 122 is acid-resistant.

In an embodiment, the metal foil portion 116 is an aluminum foil portion. In one such embodiment, the aluminum foil portion is an anodized aluminum foil portion in that the surface is anodized but the entire thickness of the foil is not anodized. In an embodiment, the metal foil portion 116 is adhered to the semiconductor region 104 or 106 by a metal seed material 114. In an embodiment, the semiconductor region 104 or 106 is a doped polycrystalline silicon region disposed on a tunneling dielectric layer 102 disposed on the substrate 100. In an embodiment, the substrate 100 is a monocrystalline silicon substrate, and the semiconductor region 104 or 106 is a doped region of the monocrystalline silicon substrate.

Referring with more specificity to FIG. 1, a plurality of alternating N-type and P-type semiconductor regions are in or above the substrate 100. In particular, the substrate 100 has disposed there above N-type semiconductor regions 104 and P-type semiconductor regions 106 disposed on a thin dielectric material 102 as an intervening material between the N-type semiconductor regions 104 or P-type semiconductor regions 106, respectively, and the substrate 100. The substrate 100 has a light-receiving surface 101 opposite a back surface above which the N-type semiconductor regions 104 and P-type semiconductor regions 106 are formed. In another embodiment, the plurality of alternating N-type and P-type semiconductor regions is a plurality of N-type and P-type doped regions within the substrate 100. A plurality of metal foil portions is electrically connected to corresponding ones of the plurality of alternating N-type and P-type semiconductor regions, and a gap 120 separates adjacent ones of the metal foil portions 116.

In an embodiment, the substrate 100 is a monocrystalline silicon substrate, such as a bulk single crystalline N-type doped silicon substrate. It is to be appreciated, however, that substrate 100 may be a layer, such as a multi-crystalline silicon layer, disposed on a global solar cell substrate. In an embodiment, the thin dielectric layer 102 is a tunneling silicon oxide layer having a thickness of approximately 2 nanometers or less. In one such embodiment, the term “tunneling dielectric layer” refers to a very thin dielectric layer, through which electrical conduction can be achieved. The conduction may be due to quantum tunneling and/or the presence of small regions of direct physical connection through thin spots in the dielectric layer. In one embodiment, the tunneling dielectric layer is or includes a thin silicon oxide layer.

In an embodiment, the alternating N-type and P-type semiconductor regions 104 and 106, respectively, are formed from polycrystalline silicon formed by, e.g., using a plasma-enhanced chemical vapor deposition (PECVD) process. In one such embodiment, the N-type polycrystalline silicon emitter regions 104 are doped with an N-type impurity, such as phosphorus. The P-type polycrystalline silicon emitter regions 106 are doped with a P-type impurity, such as boron. As is depicted in FIG. 1, the alternating N-type and P-type semiconductor regions 104 and 106 may have trenches 108 formed there between, the trenches 108 extending partially into the substrate 100. Additionally, in one embodiment, a bottom anti-reflective coating (BARC) material 110 or other protective layer (such as a layer amorphous silicon) is formed on the alternating N-type and P-type semiconductor regions 104 and 106, as is depicted in FIG. 1.

In an embodiment, the light receiving surface 101 is a texturized light-receiving surface, as is depicted in FIG. 1. In one embodiment, a hydroxide-based wet etchant is employed to texturize the light receiving surface 101 of the substrate 100 and, possibly, the trench 108 surfaces as is also depicted in FIG. 1. It is to be appreciated that the timing of the texturizing of the light receiving surface may vary. For example, the texturizing may be performed before or after the formation of the thin dielectric layer 102. In an embodiment, a texturized surface may be one which has a regular or an irregular shaped surface for scattering incoming light, decreasing the amount of light reflected off of the light receiving surface 101 of the solar cell. Referring again to FIG. 1, additional embodiments can include formation of a passivation and/or anti-reflective coating (ARC) layers (shown collectively as layer 112) on the light-receiving surface 101. It is to be appreciated that the timing of the formation of passivation and/or ARC layers may also vary.

In an embodiment, the metal foil portion 116 is an aluminum (Al) foil having a thickness approximately in the range of 5-100 microns. In one embodiment, the aluminum foil is an aluminum alloy foil including aluminum and second element such as, but not limited to, copper, manganese, silicon, magnesium, zinc, tin, lithium, or combinations thereof. In one embodiment, the aluminum foil is a temper grade foil such as, but not limited to, F-grade (as fabricated), O-grade (full soft), H-grade (strain hardened) or T-grade (heat treated). In one embodiment, the aluminum foil is an anodized aluminum foil.

In an embodiment, a plurality of metal seed material regions 114 is formed to provide a metal seed material region on each of the alternating N-type and P-type semiconductor regions 104 and 106, respectively. The metal seed material regions 114 make direct contact to the alternating N-type and P-type semiconductor regions 104 and 106. It is to be appreciated that, although depicted as individual seed material regions, a blanket seed layer may instead be formed. In an embodiment, the metal seed regions 114 are aluminum regions. In one such embodiment, the aluminum regions each have a thickness approximately in the range of 0.1 to 5 microns and include aluminum in an amount greater than approximately 97% and silicon in an amount approximately in the range of 0-2%. In other embodiments, the metal seed regions 114 include a metal such as, but not limited to, nickel, silver, cobalt or tungsten. In an embodiment, the metal foil portion 116 is adhered directly to a corresponding one of a plurality of metal seed material regions 114 by a welding joint 118.

It is to be appreciated that, in accordance with another embodiment of the present disclosure, a seedless approach may be implemented. In such an approach, metal seed material regions 114 are not formed, and the metal foil portions 116 are adhered directly to the material of the alternating N-type and P-type semiconductor regions 104 and 106. For example, in one embodiment, metal foil portions are adhered directly to alternating N-type and P-type polycrystalline silicon regions. In either case, whether metal seed portions are used or not, the process may be described as adhering the metal foil to a metallized surface of a solar cell.

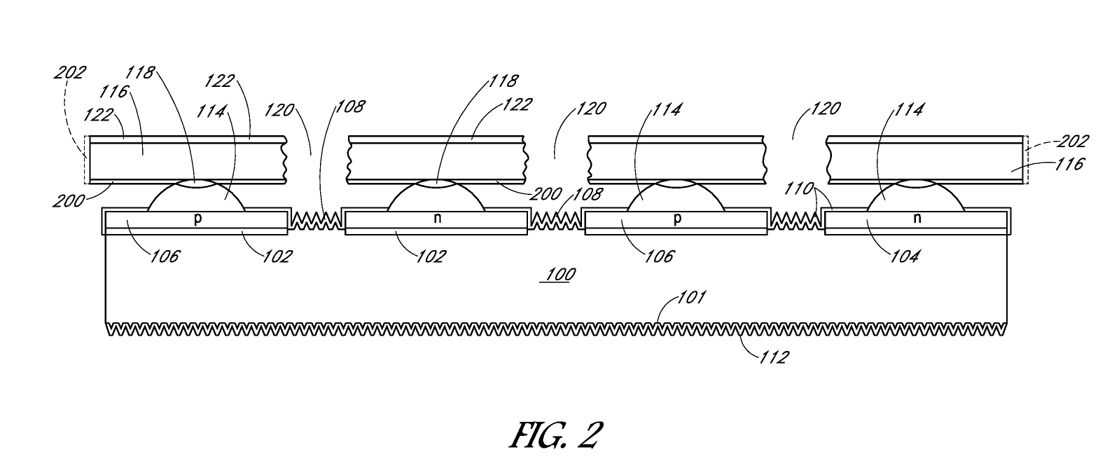

In another embodiment, the side of the metal foil portion facing the solar cell is also coated with the etch-resistant insulating film. As an example, FIG. 2 illustrates a cross-sectional view of another solar cell, in accordance with another embodiment of the present disclosure.

Referring to FIG. 2, a solar cell includes a substrate 100. A semiconductor region 104 or 106 is disposed in or above the substrate 100. A conductive contact structure 114/116 is disposed on and is in electrical contact with the semiconductor region 104 or 106. The conductive contact structure 114/116 includes a metal foil portion 116 having a first side facing the semiconductor region 104 or 106, and a second side opposite the first side. The second side of the metal foil portion is at least partially coated with an etch-resistant insulating film 122. A welding joint 118 is joining the metal foil portion 116 to the semiconductor region 104 or 106. Additionally, the first side of the metal foil portion 116 is at least partially coated with an etch-resistant insulating film 200. The etch-resistant insulating film 200 surrounds the welding joint 118.

In an embodiment, the etch-resistant insulating film 200 is a film such as described in association with etch-resistant insulating film 122. In one embodiment, the etch-resistant insulating film 200 is the same as the etch-resistant insulating film 122. In another embodiment, the etch-resistant insulating film 200 differs from the etch-resistant insulating film 122 in thickness or in composition, or both. In an embodiment, outer edges of the outermost metal foils portions 116 are further coated with an etch-resistant insulating film portion 202, as indicated by the dashed lines in FIG. 2.

In another aspect, with respect to patterning a metal foil to provide metal foil portions, previous implementations include a weld, groove and etch process, where a metal foil is ultimately etched from both top-side and bottom-side. Previous implementations also include a weld, mask and etch process, where a mask is undercut and etched from below.

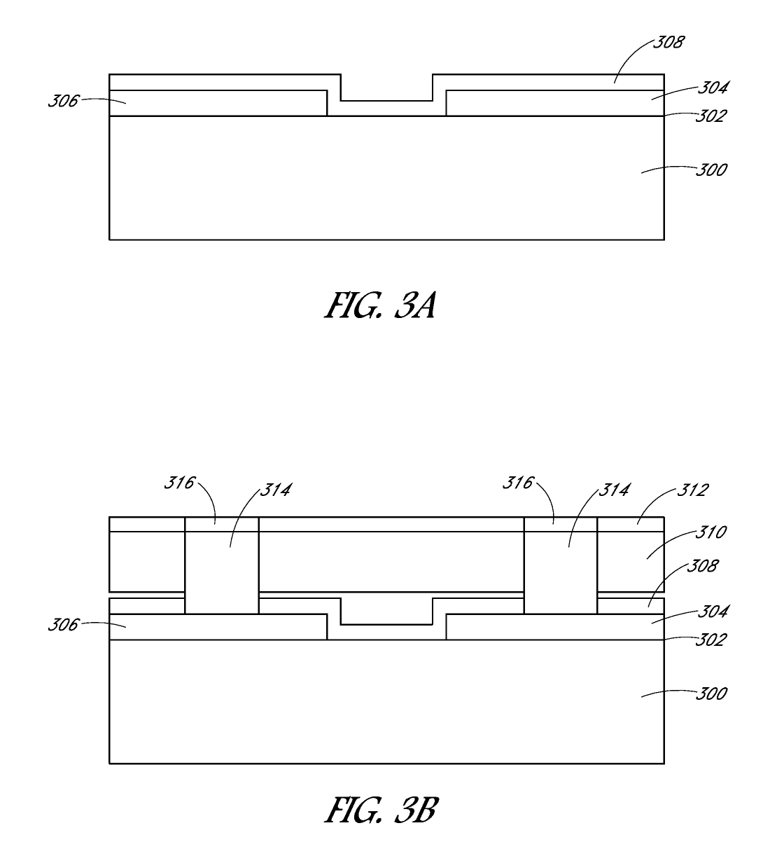

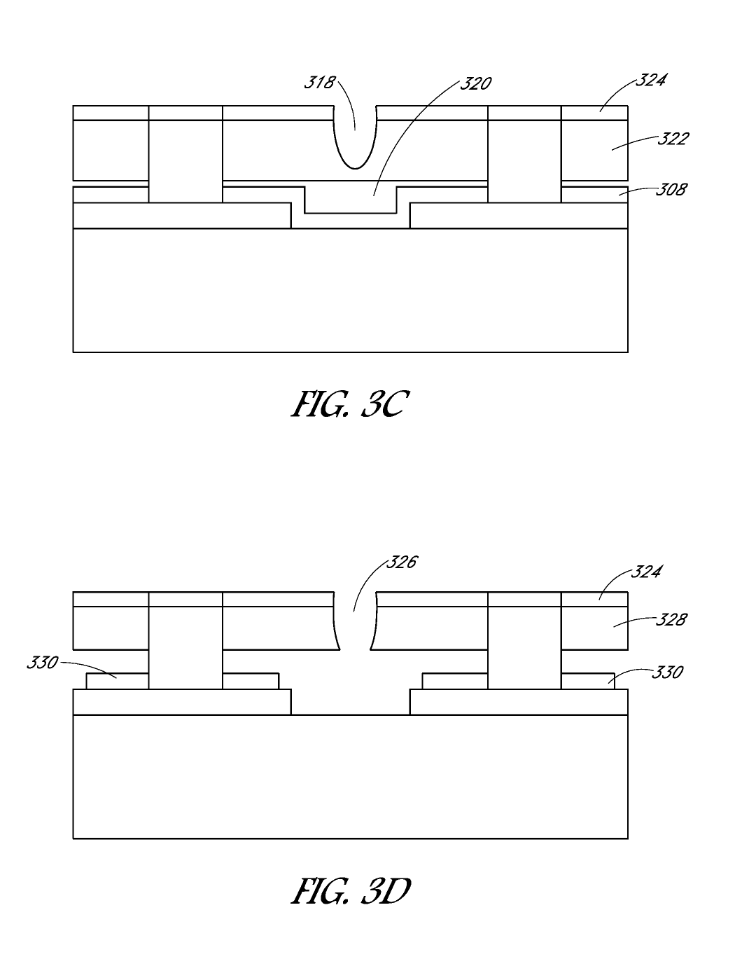

As described herein, a weld single-side coated foil, groove and etch approach involves inhibiting an etch process from a top side of a metal foil. For example, FIGS. 3A-3D illustrate cross-sectional views of various stages in the fabrication of a solar cell using foil-based metallization, in accordance with an embodiment of the present disclosure.

Referring to FIG. 3A, a solar cell substrate 300 has a P-type semiconductor region 304 and an N-type semiconductor region 306 thereon. A tunneling dielectric layer may be included between the P-type semiconductor region 304 and the substrate 300 and between the N-type semiconductor region 306 and the substrate 300 at the interface 302. A metal seed layer 308 is disposed conformally over the P-type semiconductor region 304 and the N-type semiconductor region 306.

Referring to FIG. 3B, a metal foil 310 is bonded to the structure of FIG. 3A. In particular, a single-side coated metal foil 310 having an etch-resistant film 312 coated thereon is welded to the P-type semiconductor region 304 and the N-type semiconductor region 306 by welds 314. Depending on the type of welding process performed, the etch-resistant film 312 may be modified at regions 316 as an artifact of the welding process. It is to be appreciated that the metal foil 310 may be pre-sized appropriately for the solar cell or may be first bonded as a larger sheet which is subsequently cut to shape.

In an embodiment, the welds 314 are formed by a laser process. In other embodiments, the welds 314 are formed using a tacking process involving thermal compression bonding driven by point contact force. In another embodiment, an ultrasonic bonding process is used.

FIG. 3C illustrates the structure of FIG. 3B following formation of grooves or indentations 318 in the etch-resistant film 312 and in the metal foil 310 to form patterned etch-resistant film 324 and partially patterned metal foil 322. In an embodiment, the grooves or indentations 318 are formed by a laser scribing process or an indentation process. In an alternative embodiment, the grooves or indentations 318 are formed prior to coating the metal foil 310 with the etch-resistant film 312.

In an embodiment, in the case of a laser scribing process, the metal foil 310 is laser ablated through only a portion of the metal foil 310 at regions corresponding to locations 320 between the P-type semiconductor region 304 and the N-type semiconductor region 306. In an embodiment, forming laser grooves 318 involves laser ablating a thickness of the metal foil 310 approximately in the range of 80-99% of an entire thickness of the metal foil 310. In an alternative embodiment, an indentation approach may be used in place of a laser ablation approach. In one such embodiment, the indentations 318 are formed to a depth approximately in the range of 75-90% of an entire thickness of the metal foil 310.

Referring to FIG. 3D, the grooves or indentations 318 are extended by a wet etch process to provide gaps 326 between metal foil portions 328. Additionally, in an embodiment, the metal seed layer 308 is patterned to form metal seed portions 330, as is depicted in FIG. 3D.

In an embodiment, the grooves or indentations 318 are extended by a wet etch process involving a hydroxide based etchant, such as, but not limited to, sodium hydroxide, potassium hydroxide (KOH) or tetramethylammonium hydroxide (TMAH). In one such embodiment, the patterned etch-resistant film 324 is a basic etch resistant film that inhibits loss from the upper portions of the partially patterned metal foil 322 during complete patterning of the partially patterned metal foil 322 with a basic etchant.

In another embodiment, the grooves or indentations 318 are extended by a wet etch process involving an acidic solution. In one such embodiment, the acidic solution includes phosphoric acid, acetic acid, water, and nitric acid, also referred to as a PAWN etchant. In one such embodiment, the patterned etch-resistant film 324 is an acidic etch resistant film that inhibits loss from the upper portions of the partially patterned metal foil 322 during complete patterning of the partially patterned metal foil 322 with an acidic etchant.

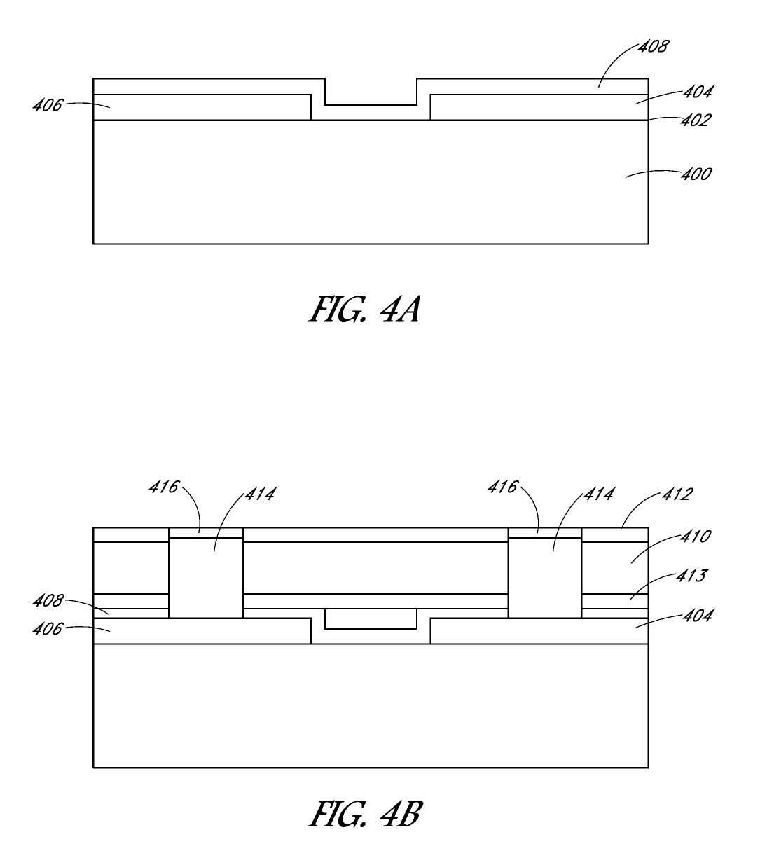

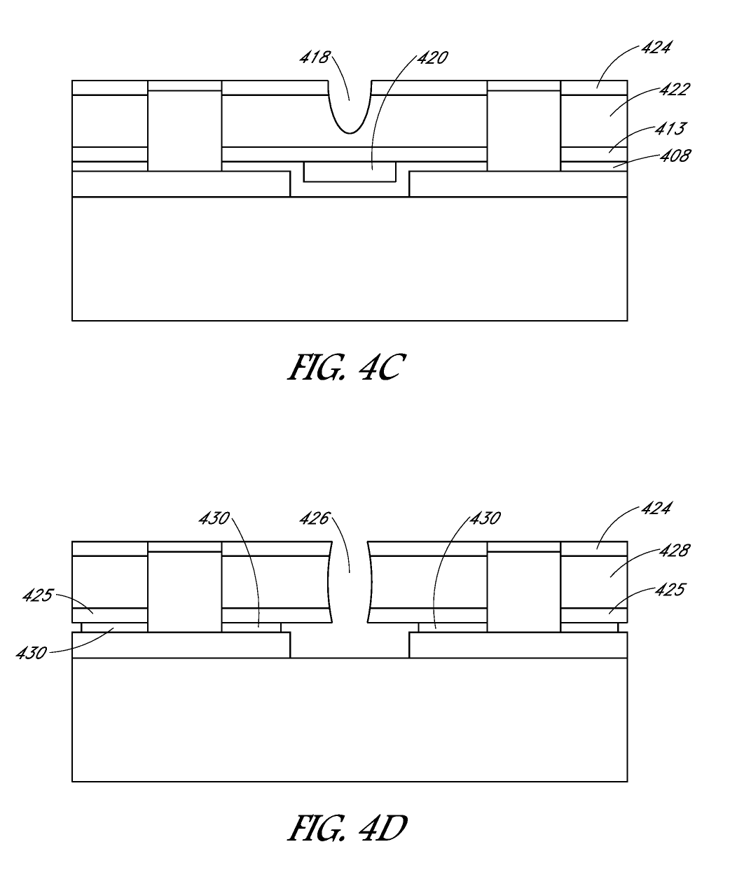

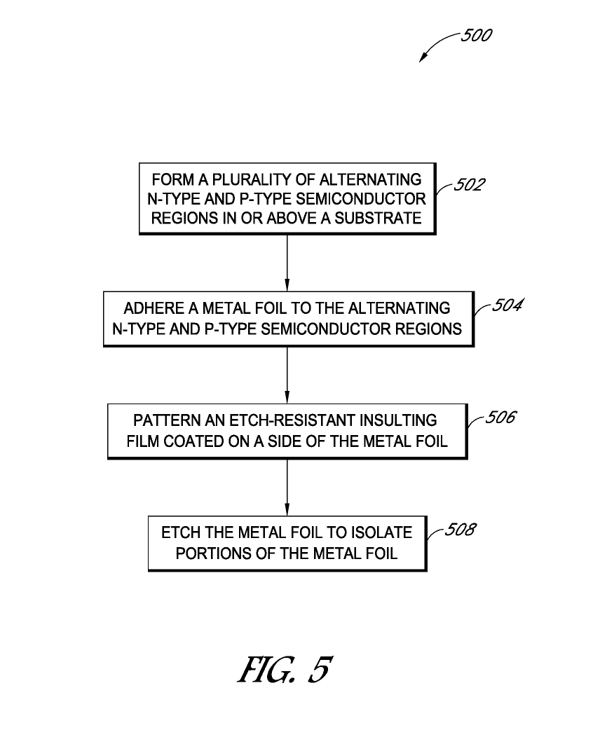

As is also described herein, a weld double-side coated foil, groove and etch approach involves inhibiting an etch process from a top side of a metal foil. For example, FIGS. 4A-4D illustrate cross-sectional views of various stages in the fabrication of another solar cell using foil-based metallization, in accordance with another embodiment of the present disclosure.

Referring to FIG. 4A, a solar cell substrate 400 has a P-type semiconductor region 404 and an N-type semiconductor region 406 thereon. A tunneling dielectric layer may be included between the P-type semiconductor region 404 and the substrate 400 and between the N-type semiconductor region 406 and the substrate 400 at the interface 402. A metal seed layer 408 is disposed conformally over the P-type semiconductor region 404 and the N-type semiconductor region 406.

Referring to FIG. 4B, a metal foil 410 is bonded to the structure of FIG. 4A. In particular, a double-side coated metal foil 410 having a first etch-resistant film 412 coated on an upper surface and a second etch-resistant film 413 coated on a lower surface is welded to the P-type semiconductor region 404 and the N-type semiconductor region 406 by welds 414. Depending on the type of welding process performed, the first etch-resistant film 412 may be modified at regions 416 as an artifact of the welding process. It is to be appreciated that the metal foil 410 may be pre-sized appropriately for the solar cell or may be first bonded as a larger sheet which is subsequently cut to shape.

In an embodiment, the welds 414 are formed by a laser process. In other embodiments, the welds 414 are formed using a tacking process involving thermal compression bonding driven by point contact force. In another embodiment, an ultrasonic bonding process is used to form welds 414.

FIG. 4C illustrates the structure of FIG. 4B following formation of grooves or indentations 418 in the etch-resistant film 412 and in the metal foil 410 to form patterned first etch-resistant film 424 and partially patterned metal foil 422. In an embodiment, the grooves or indentations 418 are formed by a laser scribing process or an indentation process. In an alternative embodiment, the grooves or indentations 418 are formed prior to coating the metal foil 410 with the etch-resistant films.

In an embodiment, in the case of a laser scribing process, the metal foil 410 is laser ablated through only a portion of the metal foil 410 at regions corresponding to locations 420 between the P-type semiconductor region 404 and the N-type semiconductor region 406. In an embodiment, forming laser grooves 418 involves laser ablating a thickness of the metal foil 410 approximately in the range of 80-99% of an entire thickness of the metal foil 410. In an alternative embodiment, an indentation approach may be used in place of a laser ablation approach. In one such embodiment, the indentations 418 are formed to a depth approximately in the range of 75-90% of an entire thickness of the metal foil 410.

Referring to FIG. 4D, the grooves or indentations 418 are extended by a wet etch process to provide gaps 426 between metal foil portions 428. Additionally, in an embodiment, the second etch-resistant film 413 is patterned to provide patterned second etch-resistant film 425, and the metal seed layer 408 is patterned to form metal seed portions 430, as is depicted in FIG. 4D.

In an embodiment, the grooves or indentations 418 are extended by a wet etch process involving a hydroxide based etchant, such as, but not limited to, sodium hydroxide, potassium hydroxide (KOH) or tetramethylammonium hydroxide (TMAH). In one such embodiment, the first patterned etch-resistant film 424 and the second patterned etch-resistant film 425 are basic etch resistant films that inhibit loss from the upper portions and from the lower portions of the partially patterned metal foil 422 during complete patterning of the partially patterned metal foil 422 with a basic etchant.

In another embodiment, the grooves or indentations 418 are extended by a wet etch process involving an acidic solution. In one such embodiment, the acidic solution includes phosphoric acid, acetic acid, water, and nitric acid, also referred to as a PAWN etchant. In one such embodiment, the first patterned etch-resistant film 424 and the second patterned etch-resistant film 425 are acidic etch resistant films that inhibit loss from the upper portions and from the lower portions of the partially patterned metal foil 422 during complete patterning of the partially patterned metal foil 422 with an acidic etchant.

In another aspect, FIG. 5 is a flowchart 500 listing operations in a method of fabricating a solar cell, in accordance with an embodiment of the present disclosure.

Referring to operation 502 of flowchart 500 of FIG. 5, a method of fabricating a solar cell includes forming a plurality of alternating N-type and P-type semiconductor regions in or above a substrate.

Referring to operation 504 of flowchart 500 of FIG. 5, the method of fabricating the solar cell also includes adhering a metal foil to the alternating N-type and P-type semiconductor regions. The metal foil has a first side facing the semiconductor region, and a second side opposite the first side. The second side of the metal foil is coated with an etch-resistant insulating film.

Referring to operation 506 of flowchart 500 of FIG. 5, the method of fabricating the solar cell also includes patterning the etch-resistant insulating film coated on the second side of the metal foil. The patterning exposes regions of the second side of the metal foil corresponding to locations between the alternating N-type and P-type semiconductor regions.

Referring to operation 508 of flowchart 500 of FIG. 5, the method of fabricating the solar cell also includes, subsequent to patterning the etch-resistant insulating film, etching the metal foil to isolate portions of the metal foil, the portions of the metal foil corresponding to the alternating N-type and P-type semiconductor regions.

In an embodiment, the etch-resistant insulating film is base-resistant, and etching the metal foil involves etching using a basic solution. In one such embodiment, the basic solution is a hydroxide solution, such as but not limited to a potassium hydroxide (KOH) solution, a sodium hydroxide (NaOH) solution, or a tetramethylammonium hydroxide (TMAH) solution.

In another embodiment, the etch-resistant insulating film is acid-resistant, and etching the metal foil involves etching using an acidic solution. In one such embodiment, the acidic solution includes phosphoric acid, acetic acid, water, and nitric acid, also referred to as a PAWN etchant.

In an embodiment, the etch-resistant insulating film is a poly(p-xylylene) polymer film coated on the second side of the metal foil by a vapor phase process. In one such embodiment, the vapor phase is formed directly from monomers. The process may involve vacuum deposition or a non-vacuum method such as vapor jet deposition. In another embodiment, the etch-resistant insulating film is a fluorocarbon film coated on the second side of the metal foil by an atmospheric plasma deposition process.

Although certain materials are described specifically with reference to above described embodiments, some materials may be readily substituted with others with such embodiments remaining within the spirit and scope of embodiments of the present disclosure. For example, in an embodiment, a different material substrate, such as a group III-V material substrate, can be used instead of a silicon substrate. Additionally, although reference is made significantly to back contact solar cell arrangements, it is to be appreciated that approaches described herein may have application to front contact solar cells as well. In other embodiments, the above described approaches can be applicable to manufacturing of other than solar cells. For example, manufacturing of light emitting diode (LEDs) may benefit from approaches described herein.

Thus, coated foil-based approaches for metallization of solar cells, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

1. A solar cell, comprising:
a substrate;
a semiconductor region disposed in or above the substrate; and
a conductive contact structure disposed on and in electrical contact with the semiconductor region, the conductive contact structure comprising a metal foil portion having a first side facing the semiconductor region, and a second side opposite the first side, wherein the second side of the metal foil portion is at least partially coated with an etch-resistant insulating film.

2. The solar cell of claim 1, wherein the etch-resistant insulating film is a poly(p-xylylene) polymer film.

3. The solar cell of claim 1, wherein the etch-resistant insulating film is a fluorocarbon film.

4. The solar cell of claim 1, wherein the metal foil portion is joined to the semiconductor region by a welding joint.

5. The solar cell of claim 1, wherein the first side of the metal foil portion is at least partially coated with the etch-resistant insulating film.

6. The solar cell of claim 1, wherein the etch-resistant insulating film is base-resistant.

7. The solar cell of claim 1, wherein the etch-resistant insulating film is acid-resistant.

8. The solar cell of claim 1, wherein the metal foil portion is an aluminum foil portion.

9. The solar cell of claim 8, wherein the aluminum foil portion is an anodized aluminum foil portion.

10. The solar cell of claim 1, wherein the etch-resistant insulating film has a thickness of at least 0.1 micron.

11. The solar cell of claim 1, wherein the metal foil portion is adhered to the semiconductor region by a metal seed material.

12. The solar cell of claim 1, wherein the semiconductor region is a doped polycrystalline silicon region disposed on a tunneling dielectric layer disposed on the substrate.

13. The solar cell of claim 1, wherein the substrate is a monocrystalline silicon substrate, and the semiconductor region is a doped region of the monocrystalline silicon substrate.

14. A solar cell, comprising:
a substrate;
a semiconductor region disposed in or above the substrate;
a conductive contact structure disposed on and in electrical contact with the semiconductor region, the conductive contact structure comprising a metal foil portion having a first side facing the semiconductor region, and a second side opposite the first side, wherein the second side of the metal foil portion is at least partially coated with an etch-resistant insulating film; and
a welding joint joining the metal foil portion to the semiconductor region, wherein the first side of the metal foil portion is at least partially coated with the etch-resistant insulating film, the etch-resistant insulating film surrounding the welding joint.

15. The solar cell of claim 14, wherein the etch-resistant insulating film is a poly(p-xylylene) polymer film.

16. The solar cell of claim 14, wherein the etch-resistant insulating film is a fluorocarbon film.

17. The solar cell of claim 14, wherein the etch-resistant insulating film is base-resistant or acid-resistant.

18. A solar cell, comprising:
a substrate;
a semiconductor region disposed in or above the substrate; and
a conductive contact structure disposed on and in electrical contact with the semiconductor region, the conductive contact structure comprising an aluminum foil portion having a first side facing the semiconductor region, and a second side opposite the first side, wherein both the first side and the second side of the aluminum foil portion have a coating thereon, the coating selected from the group consisting of a poly(p-xylylene) polymer film and a fluorocarbon film.

19. The solar cell of claim 18, wherein the aluminum foil portion is joined to the semiconductor region by a welding joint, and wherein the coating on the first side of the aluminum foil surrounds the welding joint.

20. The solar cell of claim 18, wherein the coating has a thickness of at least 0.1 micron.

21.-30. (canceled)
